(19) United States
(12) Patent Application Publication
(10) Pub. No.: US 2025/0191874 A1
(43) Pub. Date: Jun. 12, 2025

(54) OPTICAL SYSTEM FOR A PLURALITY OF PRIMARY BEAMLETS, CHARGED PARTICLE MULTI-BEAM APPARATUS AND METHOD OF FOCUSING A PLURALITY OF PRIMARY BEAMLETS

(71) Applicant: ICT Integrated Circuit Testing Gesellschaft für Halbleiterprüftechnik mbH, Heimstetten (DE)

(72) Inventor: Pieter Kruit, Delft (NL)

(73) Assignees: ICT Integrated Circuit Testing Gesellschaft für Halbleiterprüftechnik mbH, Heimstetten (DE); Technische Universiteit Delft, CN Delft (NL)

(21) Appl. No.: 18/536,914

(22) Filed: Dec. 12, 2023

(51) Int. Cl. H01J 37/153; H01J 37/12; H01J 37/147; H01J 37/21

(52) U.S. Cl. CPC H01J 37/153; H01J 37/12; H01J 37/1477; H01J 37/21; H01J 2237/1516; H01J 2237/1532

(57) ABSTRACT

An optical system configured to focus a plurality of primary beamlets of a multi-beam apparatus is described. The optical system a first multipole arrangement with a plurality of first multipoles to provide a first astigmatism and a second multipole arrangement with a plurality of second multipoles to provide a second astigmatism, wherein the first astigmatism and the second astigmatism compensate each other. The optical system further includes three or more electrodes forming a plurality of electrostatic lenses for the plurality of primary beamlets, each electrode with an electrode body and a plurality of openings in the electrode body for guiding one primary beamlet of the plurality of primary beamlets through one opening of the plurality of openings; and an electrical connection to provide a potential to the electrode body at the plurality of openings.

### FIELD

Embodiments relate to charged particle beam devices, for example, for inspection system applications, testing system applications, defect review or critical dimensioning applications or the like. Embodiments also relate to methods of operation of a charged particle beam device. More particularly, embodiments relate to charged particle beam devices being multi-beam high throughput electron beam inspection (EBI). Specifically, embodiments relate to an optical system configured to focus a plurality of primary beamlets of a multi-beam apparatus, a charged particle multi-beam apparatus, and a method of focusing a plurality of primary beamlets of charged particles on a specimen.

### BACKGROUND

Modern semiconductor technology is highly dependent on an accurate control of the various processes used during the production of integrated circuits. Accordingly, the wafers are inspected repeatedly in order to localize problems as early as possible. Furthermore, a mask or reticle is also inspected before the actual use during wafer processing in order to make sure that the mask accurately defines the respective pattern. The inspection of wafers or masks for defects may include the examination of the whole wafer or mask area, e.g. for 300 mm wafer production. Especially, the inspection of wafers during wafer fabrication beneficially includes the examination of the whole wafer area in such a short time that production throughput is not limited by the inspection process.

Scanning electron microscopes (SEM) have been used to inspect wafers. The surface of the wafer is scanned using e.g. a single finely focused electron beam. When the electron beam hits the wafer, secondary electrons and/or backscattered electrons, i.e. signal electrons, are generated and measured. A pattern defect at a location on the wafer is detected by, for example, comparing an intensity signal of the secondary electrons to, for example, a reference signal corresponding to the same location on the pattern. However, because of the increasing demands for higher resolutions, scanning the entire surface of the wafer takes a long time. Accordingly, using a conventional (single-beam) Scanning Electron Microscope (SEM) for wafer inspection is difficult, since the approach does not provide the respective throughput.

Wafer and mask defect inspection in semiconductor technology needs high resolution and fast inspection tools, which cover both full wafer or mask application or hot spot inspection. Electron beam inspection gains increasing importance because of the limited resolution of light optical tools, which are not able to handle the shrinking defect sizes. In particular, from the 20 nm node and beyond, the high-resolution potential of electron beam-based imaging tools is in demand to detect all defects of interest.

In a multi-beam instrument, a plurality of electron beams may be used to inspect or image areas of the specimen, for example, a wafer. The plurality of beams may be focused with an electrostatic lens having, for example, an opening for trespassing of each of the beamlets. A correction of focal lengths of the beamlets with an electrostatic lens, for example, by having a lens electrode with individual lens voltage differences per beamlets, can be challenging in light of the plurality of aspects.

In view of the above, a lens for a plurality of primary beamlets, for example, in a charged particle multi-beam device, a charged particle multi-beam apparatus, and a method of focusing a plurality of primary beamlets are provided that are improved as compared to previous attempts.

### SUMMARY

In light of the above, an optical system configured to focus a plurality of primary beamlets, a charged particle multi-beam apparatus, and method of focusing a plurality of primary beamlets are provided. Further aspects, advantages, and features are apparent from the dependent claims, the description, and the accompanying drawings.

According to an embodiment, an optical system configured to focus a plurality of primary beamlets of a multi-beam apparatus is provided. The optical system includes a first optical component with a first multipole arrangement with a plurality of first multipoles of an order of four or more, each first multipole of the plurality of first multipoles is configured to provide a first astigmatism and a second multipole arrangement with a plurality of second multipoles of an order of four or more, each second multipole of the plurality of second multipoles is configured to provide a second astigmatism, wherein the first astigmatism and the second astigmatism compensate each other. The optical system further includes a second optical component having three or more electrodes forming a plurality of electrostatic lenses for the plurality of primary beamlets, each electrode with an electrode body and a plurality of openings in the electrode body for guiding one primary beamlet of the plurality of primary beamlets through one opening of the plurality of openings; and an electrical connection to provide a potential to the electrode body at the plurality of openings, wherein a first multipole of the plurality of first multipoles and a second multipole of the plurality of second multipoles form a pair of corresponding multipoles configured for individual focus adjustment of a primary beamlet of the plurality of primary beamlets.

According to an embodiment, a charged particle multi-beam apparatus having a plurality of primary beamlets focused on a specimen is provided. The apparatus including a charged particle emitter for a primary charged particle beam; an aperture lens array for generating a plurality of primary beamlets from the primary charged particle beam; and an optical system according to any of the embodiments of the present disclosure.

According to an embodiment, a method of focusing a plurality of primary beamlets of charged particles on a specimen is provided. The method includes focusing the plurality of primary beamlets with a plurality of electrostatic lenses with three or more electrodes and a plurality of openings in each of the three or more electrodes; and adjusting a focal length individually for each of the plurality primary beamlets by introducing a first astigmatism to a primary beamlet of the plurality of primary beamlets and a second astigmatism to the primary beamlet of the plurality of primary beamlets, the first astigmatism and the second astigmatism compensate each other and provide an individual focus adjustment of the primary beamlet.

Embodiments are also directed at apparatuses for carrying out the disclosed methods and include apparatus parts for performing each described method features. The method features may be performed by way of hardware components, a computer programmed by appropriate software, by any combination of the two or in any other manner. Furthermore, embodiments are also directed at methods which the described apparatus operates with. Embodiments include method features for carrying out every function of the apparatus.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1 shows a schematic view of an optical system having a first optical component and a second optical component according to embodiments described herein;

FIG. 2A shows a schematic view of a portion of a charged particle beam device for specimen inspection illustrating the focusing of a beamlet;

FIG. 2B shows a comparison of embodiments of the present disclosure as compared to FIG. 2A;

FIG. 3 shows a schematic view of an optical system having a first optical component and a second optical component according to embodiments described herein;

FIG. 4 shows a schematic view of a charged particle beam device for specimen inspection according to embodiments described herein;

FIG. 5 shows a flow chart illustrating methods of aligning an array of primary beamlets according to embodiments of the present disclosure.

### DETAILED DESCRIPTION OF EMBODIMENTS

Reference will now be made in detail to the various embodiments, one or more examples of which are illustrated in the figures. Within the following description of the drawings, the same reference numbers refer to the same components. The differences with respect to individual embodiments are described. Each example is provided by way of explanation and is not meant as a limitation. Further, features illustrated or described as part of one embodiment can be used on or in conjunction with other embodiments to yield yet a further embodiment. The description is intended to include the modifications and variations.

Without limiting the scope of protection of the present application, in the following, the charged particle beam device or components thereof will exemplarily be referred to as a charged particle beam device including a primary electron beam or primary electron beamlets and the detection of secondary or backscattered particles, such as electrons. As described herein, discussions and descriptions relating to the detection are exemplarily described with respect to electrons in scanning electron microscopes. Other types of charged particles, e.g. positive ions, could be emitted and/or detected by the device in a variety of different instruments. Embodiments relate to a primary beam, primary beamlets, and one or more signal beams of e.g. electrons. The primary beam, the primary beamlets, and/or the one or more signal beams may be provided by other charged particles as electrons. Further, the one or more signal beams may include other signals, such as corpuscles as described above.

According to embodiments herein, which can be combined with other embodiments, a signal (charged particle) beam, or a signal (charged particle) beamlet is referred to as a beam of secondary particles, i.e. secondary and/or backscattered electrons. The signal beam or secondary beam is generated by the impingement of the primary beam or primary beamlets on a specimen or by backscattering of the primary beam or the primary beamlets from the specimen. A primary charged particle beam or a primary charged particle beamlet is generated by a particle beam source and is guided and deflected on a specimen to be inspected or imaged.

A “specimen” or “sample” as referred to herein, includes, but is not limited to, wafers, semiconductor wafers, semiconductor workpieces, photolithographic masks and other workpieces such as memory disks and the like. Embodiments may be applied to any workpiece on which material is deposited or any workpiece which is structured. According to some embodiments, which can be combined with other embodiments described herein, the apparatus and the method are configured for or are applied for electron beam inspection, for critical dimensioning applications and defect review applications.

Embodiments of the present disclosure provide an optical system for a multi-electron beam apparatus, a multi-electron beam apparatus, and a method of focusing multiple beamlets, wherein individual beam-focusing of the beamlets can be provided. As compared to having individual beam-focusing in an electrostatic lens, for example, a lens having three or more lens electrodes such as an Einzel lens, lower voltages for individual focusing can be provided. Particularly for a plurality of primary beamlets such as 50 beamlets or more, 200 beamlets or more, or even 1000 beamlets or more, the lower voltage for individual focus adjustment allows for improved manufacturing options. Since the high number of beamlets may be packed closely together, a plurality of high voltages of, for example, a few hundred volts or above are difficult or impossible to provide in the small area. There is not sufficient space for the insulation of the supply lines.

Embodiments of the present disclosure provide a combination of an electrostatic lens with openings for the beamlets and a double multipole array, for example, a double quadrupole array, for individual beam-focusing in a multi-beam apparatus.

As described above, in a multi-beam apparatus, the focus position (focal length or focal strength) of individual beamlets can beneficially be adjusted. In a traditional Einzel lens, high voltages are required. Embodiments of the present disclosure utilized two quadrupoles per beamlet. Focus adjustment can be provided with low voltages.

FIG. 1 shows an optical system 100 as a portion of a multi-beam apparatus. A plurality of primary beamlets are guided towards the specimen 20 supported on a specimen stage 102. FIG. 1 exemplarily shows three primary beamlets 10-1, 10-2, and 10-3. According to embodiments of the present disclosure, there can be 50 or more primary beamlets, such as 200 or more primary beamlets, or even a thousand or more primary beamlets. The optical system 100 includes a first optical component and a second optical component. The first optical component is provided by the first multipole arrangement 120 and a second multipole arrangement 130. The second optical component is provided by an electrostatic lens 110, for example an objective lens.

The electrostatic lens 110 includes three or more electrodes. FIG. 1 shows a first electrode 112, a second electrode 114, and a third electrode 116. Each of the electrodes include a plurality of openings 113. Each opening of the plurality of openings corresponds to one primary beamlet. The openings 113 are provided in an electrode body of the respective electrode. Each of the electrode bodies is biased to a potential in order to provide a voltage between the electrodes for focusing of the primary beamlets. An electrostatic lens is provided for each of the primary beamlets. The voltages between the electrodes, or the potentials of the electrodes, can be provided by one or more power supplies. Each electrode can be connected to a power supply, e.g. a single power supply, by an electrical connection. One power supply 119 is illustrated in FIG. 1.

Each electrode of the electrostatic lenses is biased to common potential. Accordingly, each of the plurality of primary beamlets is focused with essentially the same focusing strength. It may be beneficial to focus each beamlet in a slightly different plane, because e.g. of local sample charging, some remnant curvature of field or a tilted sample. For a single beam system with an electrostatic objective lens, focusing is done by changing the voltage on one of the lens electrodes. Since the electrodes of the electrostatic lens 110 are common for all lenses, a change in voltage of one of the electrodes would influence all primary beamlets. An array of individual lens electrodes may be added to the electrostatic lens with means to apply individual voltages to each element of the array. The inventors have found that to reach a sufficient range of defocus or focus adjustment, the voltage range would be hundreds of volts with respect to ground, or tens of volts with respect to a high bias voltage of one of the common lens electrodes. Accordingly, embodiments of the present disclosure provide the first optical component with the first multipole arrangement and the second multipole arrangement.

The first optical component with the first multipole arrangement and the second multipole arrangement is for focusing of the beamlets, i.e. focus adjustment. The second optical component having the electrostatic lens for the plurality of primary beamlets, i.e. the electrostatic lenses for each beamlet, is for focusing of the beamlets. Accordingly the first optical component can be considered a portion of a lens (focus adjustment) and the second optical component can be considered a portion of the lens (common focusing).

FIG. 1 shows the first multipole arrangement 120 and the second multipole arrangement 130. Each of the multipole arrangements has an order of four or more. For example, quadrupoles or octupoles may be used. The first multipoles 122 can be individually excited. The second multipoles 132 can be individually excited. This is exemplarily indicated by a power supply 140 having a plurality of connections. The first multipole arrangement 120 is provided between a charged particle beam source (not shown in FIG. 1) and the specimen stage 102. The second multipole arrangement 130 is provided downstream of the first multipole arrangement. The second multipole arrangement can be provided between the first multipole arrangement and the specimen stage 102.

As schematically indicated in FIG. 1, the primary beamlets, for example primary beamlets 10-1, 10-2, and 10-3, have a crossover within the multi-beam apparatus. The first multipole arrangement and the second multipole arrangement are provided between the crossover and the specimen stage. Yet further, according to some embodiments, which can be combined with other embodiments described herein, the first multipole arrangement and the second multipole arrangement are provided upstream of the electrostatic lens 110. The first multipole arrangement and the second multipole arrangement can be adjacent optical components along an optical axis of the primary beamlet.

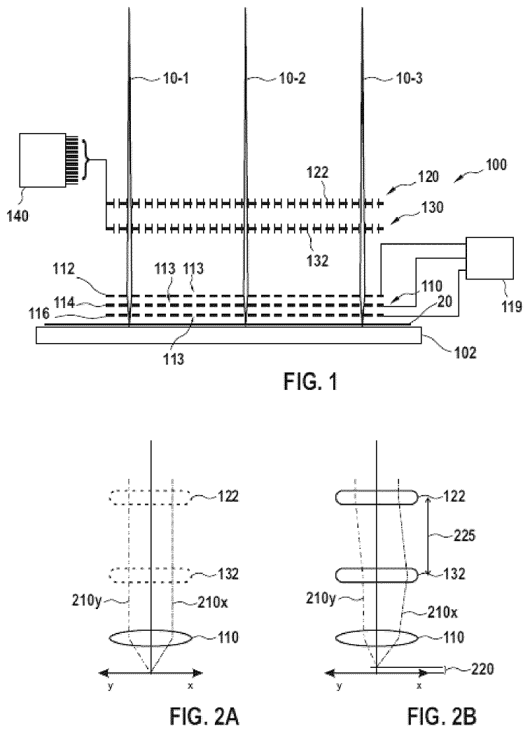

FIGS. 2A and 2B illustrate the effect of an optical system according to embodiments of the present disclosure. One primary beamlet is exemplarily shown in a x-z-plane, as illustrated by beam projection 210x and in an y-z-plane as illustrated by beam projection 210y. In FIG. 2A, the electrostatic lens 110 focuses the primary beamlet in an imaging plane. A stigmatic focus is provided. As illustrated by the dashed lines for first multipole 122 of the first multipole arrangement and a second multipole 132 of the second multipole arrangement in FIG. 2A, the multipoles are switched off in FIG. 2A, i.e. the multipoles do not influence the primary beamlet.

In FIG. 2B, the first multipole 122 introduces the first astigmatism. The beam projection 210x shows a widening of the primary beamlet in the x-z-plane. The beam projection 210y shows a narrowing of the primary beamlet in the y-z-plane. The second multipole 132 introduces a second astigmatism. The beam projection 210x shows a narrowing or a reduced widening of the primary beamlet in the x-z-plane. The beam projection 210y shows a widening or a reduced narrowing of the primary beamlet in the y-z-plane. The electrostatic lens 110 focuses the primary beamlet at a position, which is offset by the distance 220 as compared to the previous imaging plane. The first astigmatism and the second astigmatism compensate each other. A stigmatic focus is generated.

According to some embodiments, which can be combined with other embodiments described herein, a distance 225 between the first multipole arrangement and the second multipole arrangement can be 5 mm or above, particularly 5 mm to 50 mm. Accordingly, the primary beamlet travels along the optical axis, wherein the astigmatism increases (i.e. a focus and de-focus increases), before the astigmatism is corrected by a second multipole of the second multipole arrangement. According to yet further embodiments, which can be combined with other embodiments described herein, a distance of the first multipole arrangement from one of the three or more electrodes can be 70 mm or less.

Embodiments of the present disclosure use multipoles generating a quadrupole field, for example, quadrupoles, instead of round lenses for individually adjusting the focus of the primary beamlets in a multi-beam apparatus. A multi-beam apparatus, such as a multi-beam scanning electron microscope, has an array of electrostatic lenses as a second optical component. The second optical component provides a common focus length. An array of first multipoles and an array of second multipoles are utilized for individual focus adjustment of the primary beamlets, e.g. as a first component.

According to an embodiment, an optical system configured to focus a plurality of primary beamlets of a multi-beam apparatus is provided. The optical system includes a first optical component having a first multipole arrangement with a plurality of first multipoles of an order of four or more, each first multipole of the plurality of first multipoles is configured to provide a first astigmatism and a second multipole arrangement with a plurality of second multipoles of an order of four or more, each second multipole of the plurality of second multipoles is configured to provide a second astigmatism, wherein the first astigmatism and the second astigmatism compensate each other. The optical system further includes a second optical component having three or more electrodes forming a plurality of electrostatic lenses for the plurality of primary beamlets. Each electrode includes an electrode body and a plurality of openings in the electrode body for guiding one primary beamlet of the plurality of primary beamlets through one opening of the plurality of openings and an electrical connection to provide a potential to the electrode body at the plurality of openings, wherein a first multipole of the plurality of first multipoles and a second multipole of the plurality of second multipoles form a pair of corresponding multipoles configured for individual focus adjustment of a primary beamlet of the plurality of primary beamlets. According to some embodiments, a plurality of first multipoles and a plurality of second multipoles forms pair of corresponding multipoles configured for individual focus adjustment of each primary beamlet of the plurality of primary beamlets. According to some embodiments, each first multipole of the plurality of first multipoles and each second multipole of the plurality of second multipoles form a pair of corresponding multipoles configured for individual focus adjustment of each primary beamlet of the plurality of primary beamlets.

According to some embodiments, which can be combined with other embodiments described herein, the first multipole arrangement and the second multipole arrangement can include a plurality of electrical connections to allow for individual adjustment of potentials per multipole. Each of the first multipoles and the second multipoles can be quadrupoles. For example, the poles of the first quadrupoles and the poles of the second quadrupoles can be offset by an angle of 90° (the structure can have an offset of) 0°, particularly in order to have the first astigmatism and the second astigmatism compensate each other, as e.g. shown in FIG. 2B.

According to some embodiments, which can be combined with other embodiments described herein, each of the first multipoles and the second multipoles are octupoles. A further correction, e.g. correction higher order astigmatism such as sixtupole (3-fold astigmatism) or octupole (4-fold astigmatism), may be corrected. According to some embodiments, which can be combined with other embodiments described herein, the plurality of openings in the electrode body can have a pitch of 0.5 mm or above. The pitch with a minimum size allows for sufficiently large openings in the electrodes of the electrostatic lens. Accordingly, a total current on the wafer can be, for example, 1 μA or above, such as, for example, 2 μA, or above. Thus, a good overall throughput of imaging and or inspecting can be added, particularly at resolution of 10 nm or below, e.g. 5 nm or below, such as 1 nm to 5 nm.

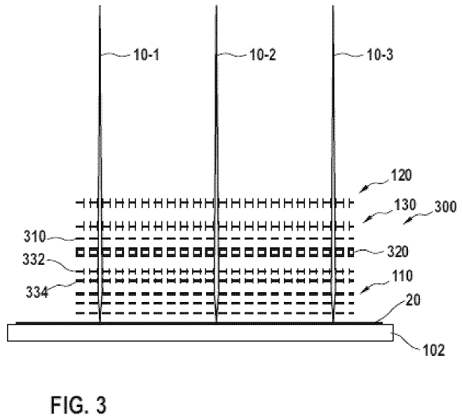

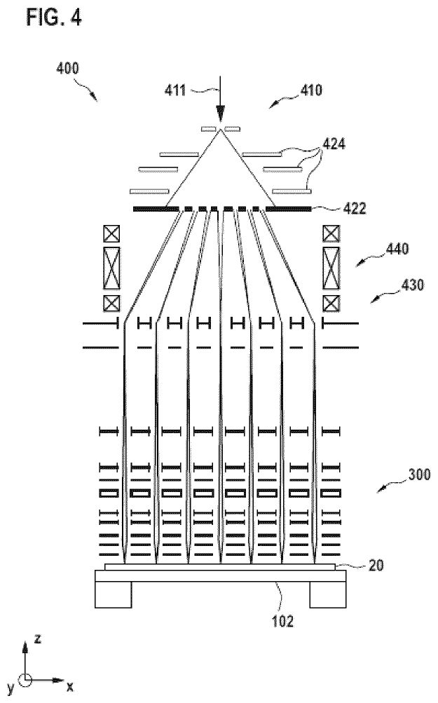

FIG. 3 illustrates further embodiments of portion 300 of a multi-beam apparatus having an optical system for focusing a plurality of primary beamlets. FIG. 4 shows a charged particle multi-beam apparatus exemplarily having an optical system as shown in FIG. 3. FIG. 3 shows, similar to FIG. 1, a plurality of primary beamlets that are guided towards the specimen 20 supported on a specimen stage 102. FIG. 3 exemplarily shows three primary beamlets 10-1, 10-2, and 10-3. Further to the optical system having the electrostatic lens 110, the first multipole arrangement 120, and the second multipole 130, further components are provided. The embodiments and implementations described in the present disclosure with respect to the electrostatic lens, the first multipole arrangement 120, and the second multipole arrangement 130, may similarly apply to the embodiments described with respect to FIG. 3.

Particularly for embodiments, in which the first multipole arrangement 120 is provided as octupole, the field of a condenser lens may be provided to the first multipole arrangement, particularly in addition to the quadrupole field introducing the first astigmatism. A second condenser lens electrode can be provided downstream of the second multipole arrangement 130. The plurality of primary beamlets can be scanned with a pre-scan-deflector 332 and a scan-deflector 334. Each of the pre-scan-deflector and the scan-deflector may have a first stage for scanning the plurality of primary beamlets in a first direction, for example, x-direction over the specimen 20 and may have a second stage for scanning the plurality of primary beamlets in the second direction, for example, y-direction over the specimen. The first direction and the second direction are different and can be particularly perpendicular to each other.

The pre-scan deflector 332 enables the scanning of the primary beamlets together with the scan-deflector 334, such that the primary beamlets travel through the openings in the electrostatic lens substantially on an axis of a respective opening. Upon impingement of the primary beamlets on the specimen 20, each primary beamlet releases a signal beamlet, e.g. backscattered and/or secondary electrons. An extraction field provided by the lower electrode, i.e. third electrode 116 shown in FIG. 1, or by a further electrode between the electrostatic lens 110 and the specimen accelerates the plurality of signal beamlets towards the electrostatic lens, and particularly through the electrostatic lens. Each signal beamlet of the plurality of signal beamlets travels through a respective opening in the electrodes of the electrostatic lens. The signal beamlets can be detected by an array of detectors 320. Accordingly, a detection signal can be generated per signal beamlet.

FIG. 4 shows a charged particle multi-beam apparatus 400. The charged particle multi-beam apparatus 400 includes a multi-beam generator. The multi-beam generator may include a charged particle beam source 410, two or more electrodes, and an aperture lens array. The charged particle beam source 410 includes a particle beam emitter 411, which emits a primary charged particle beam, for example an electron beam. Particularly, a single emitter can be provided, for example a high brightness emitter. A charged particle beam emitter as described herein may be a cold field emitter (CFE), a Schottky emitter, a thermal field emitter (TFE) or another high current, high brightness charged particle beam source (such as an electron beam source). A high current is considered to be 0.5 mA/sr or above such as 0.5 mA/sr to 1 mA/sr.

According to embodiments described herein, the multi-beam generator is configured to generate an array of primary beamlets. The charged particle beam source 410 emits a primary beam. The aperture lens array or multi-aperture lens plate 422 generates primary beamlets from the primary beam. The one or more electrodes and the multi-aperture lens plate may operate as electrodes of an electrostatic lens. Accordingly, the one or more electrodes can be lens electrodes. Particularly, the one or more electrodes can include an opening for the primary beam. The multi-aperture lens plate includes openings for generating the primary beamlets. The one or more electrodes, i.e. electrodes common to the beamlets and the multi-aperture lens plate act together, particularly as if the beamlets would be influenced by individual lenses corresponding to the openings or apertures in the multi-aperture lens plate. The multi-aperture lens plate includes a plurality of apertures. The aperture lens array (ALA) or multi-aperture plate generates one primary beamlet per aperture. In addition, the lenses generated for the beamlets by the electrodes and the multi-aperture lens plate focuses each individual primary charged particle beamlet in a plane.

Accordingly, the charged particle beam source and the ALA constitute a multi-beam generator for creating multiple primary charged particle beamlets, which are directed towards a surface of a sample.

The beamlets generated by the aperture lens array are collimated with a collimator 430. The collimator 430 can be provided in or near the plane of primary beamlet focus. Near the plane is to be understood to have the collimator 430 within 20% of the focal length of the ALA. By arranging the plane, i.e. the focus plane of the ALA, in or near the collimator, distortions of the individual electron beamlets due to aberrations of the deflection, can be reduced.

For example, the collimator can include at least one of a deflector array and a lens. Accordingly, the diverging pattern or array of primary beamlets is redirected by the collimator 430. For example, the primary beamlets can be parallel or essentially parallel after the collimator. The collimated beamlets may travel essentially parallel and/or along optical axes onto a sample or a specimen 20.

According to implementations of the present disclosure, which can be combined with embodiments described herein, a plurality, for example, 4 or 8 deflection electrodes can be provided per primary beamlet in the collimator 430. Each primary beamlet can be deflected individually.

As shown in FIG. 4, according to some embodiments, an alignment system 440 can be provided between the ALA and the collimator 430. The alignment system can include a first coil or set of coils for rotating the array of primary beamlets. Further, beam alignment coils can be provided. Yet further, a coil or a set of coils for pitch adjustment in the array of primary beamlets can be provided.

According to some embodiments, which can be combined with other embodiments described herein, an optical system according to embodiments of the present disclosure can include or can be an objective lens in a charged particle multi-beam apparatus 400. The electrostatic lens 110 includes three or more electrodes having an array of holes or openings. The plurality of electrodes may act as electrostatic lenses on the primary beamlets passing through corresponding holes and openings of the plurality of electrodes. The objective lens unit can be provided as a deceleration lens. The plurality of electrodes may be set to potentials decelerating the primary beamlets before impinging on the specimen. According to embodiments described herein, one detection surface can be provided per signal beamlet in the detector array 320.

According to one embodiment, a charged particle multi-beam apparatus having a plurality of primary beamlets focused on a specimen is provided. The charged particle multi-beam apparatus includes a charged particle emitter for a primary charged particle beam and an aperture lens array for generating a plurality of primary beamlets from the primary charged particle beam. Further, the charged particle multi-beam apparatus includes an optical system according to any of the embodiments of the present disclosure. For example, the optical system can be an objective lens configured to focus a plurality of primary beamlets on the specimen. The charged particle multi-beam apparatus can be a multi-beam scanning electron microscope. According to some embodiments, which can be combined with other embodiments described herein, the charged particle multi-beam apparatus can include a common pre-scan-deflector array configured to scan the primary beamlets and a common scan-deflector array configured to scan the primary beamlets over the specimen. For example, the pre-scan-deflector array and the deflector array may be synchronized such that the scanning of the primary beamlets is generated by the combined action of the pre-scan-deflector array and the scan-deflector array.

According to some embodiments, which can be combined with other embodiments described herein, the charged particle multi-beam apparatus may further include a detector array position between the plurality of electrostatic lenses and the aperture lens array. Particularly, the detector array may be positioned between the electrostatic lens 110 and the first optical component with the first multipole arrangement and the second multiple arrangement. According to some embodiments, which can be combined with other embodiments described herein, a detector array may additionally or alternatively be provided between the electrostatic lens and the sample (or the sample stage). The detector array can be configured to detected signal beamlets generated upon impingement of the primary beamlets on the specimen. As described above, some implementations may additionally or alternatively include a collimator downstream of the aperture lens array. The collimator can be configured to deflect the plurality of primary beamlets with respect to each other. Further, additionally or alternatively an alignment system between the aperture lens array and the collimator can be provided, the alignment system being configured to provide at least one of a rotation, a deflection and a pitch adjustment of an array of primary beamlets provided by the plurality of primary beamlets.

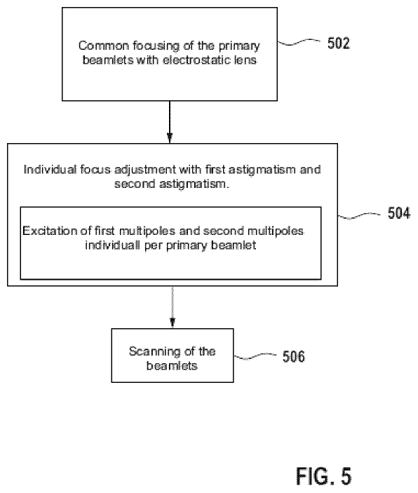

FIG. 5 shows a flowchart illustrating methods according to embodiments of the present disclosure. According to an embodiment, a method of focusing a plurality of primary beamlets of charged particles on the specimen is disclosed. In operation 502, the plurality of primary beamlets are focused with a plurality of electrostatic lenses. The electrostatic lenses are provided by 3 or more electrodes and the plurality of openings in each of the 3 or more electrodes. The focusing of the plurality of primary beamlets is provided with a common excitation, e.g. potentials on or voltages between the electrodes, for the primary beamlets. According to operation 504, the focal lengths for each primary beamlet is individually adjusted. The first astigmatism is introduced for a primary beamlet and a second astigmatism, compensating the first astigmatism is introduced for the primary beamlet. The introduction of the first astigmatism in the second astigmatism provide for an individual focus adjustment of the primary beamlet.

As illustrated for operation 504, the plurality of first multipoles and the plurality of second multipoles are individually excited per primary beamlet for focus adjustment. According to some embodiments, which can be combined with other embodiments described herein, the adjusting of the focal strength includes providing four or more first voltages to each first multipole of a plurality of first multipoles to generate the first astigmatism and providing second voltages to each second multipole of a plurality of second multipoles to generate the second astigmatism.

The two or more first voltages and the two or more second voltage can be a first voltage value, of e.g. +V, provided to opposing electrodes of a multipole and a second voltage value, of e.g. −V, provided to further opposing electrodes of the multipole. It may also be possible that one pair of opposing electrodes is on ground potentials. Accordingly, the two or more voltages may be provided by one power supply or by two power supplies. For a multipole, further power supplies can be provided. Further, in the event of opposing electrodes having (slightly) different voltages, a power supply may also be provided per electrode.

As illustrated by operation 506, for imaging areas below each of the primary beamlets, the plurality of primary beamlets can be scanned over the specimen 20. A multi-beam scanning electron microscope can be provided.

The focus adjustment can be at least 0.3 micron per volt for the voltages applied to the multipoles, e.g. for at least one of the four or more first voltages and one of four or more second voltages. For example, the focus adjustment can be at least 0.5. micron per volt, such as at least 1 micron per volt. As described above, an individual correction voltage to an electrostatic lens would be several hundred volts. The electrostatic lens is influenced by a voltage difference between two electrodes. Particularly for high beam energies, the electric field strength needs to be high, i.e. there are high voltages between the electrodes or the electrodes need to be close together. Due to an increasing de-focus upon increased distances between the first quadrupole in the second quadrupole, low voltages can be utilized for focus adjustment. A distance of the plurality of first multipoles and the plurality of second multipoles can be 5 mm or above, particularly wherein a distance of the plurality of first multipoles and the plurality of second multipoles is 5 mm to 50 mm. According to embodiments of the present disclosure, for example, each of the four or more first voltages and four or more second voltages are below 100 V for correcting the focus position of all of the plurality of primary beamlets in a plane of the specimen, e.g. by 50 μm or below or by 10 μm or below.

As an example, the voltage of −4.7 volts at a first quadrupole and 5 V at the second quadrupole may shift the focus by more than 6 μm. According to some embodiments, which can be combined with other embodiments described herein, the absolute value of the voltage at the first quadrupole may be lower than the absolute value of the voltage at the second quadrupole, the second quadrupole being closer to the specimen.

The present disclosure discloses a plurality of embodiments, some of which are as described below:

Embodiment 1. An optical system configured to focus a plurality of primary beamlets of a multi-beam apparatus, comprising: a first optical component, comprising: a first multipole arrangement with a plurality of first multipoles of an order of four or more, each first multipole of the plurality of first multipoles is configured to provide a first astigmatism; and a second multipole arrangement with a plurality of second multipoles of an order of four or more, each second multipole of the plurality of second multipoles is configured to provide a second astigmatism, wherein the first astigmatism and the second astigmatism compensate each other; the optical system further comprising: a second optical component, comprising: three or more electrodes forming a plurality of electrostatic lenses for the plurality of primary beamlets, each electrode comprising: an electrode body and a plurality of openings in the electrode body for guiding one primary beamlet of the plurality of primary beamlets through one opening of the plurality of openings; and an electrical connection to provide a potential to the electrode body at the plurality of openings; wherein a first multipole of the plurality of first multipoles and a second multipole of the plurality of second multipoles form a pair of corresponding multipoles configured for individual focus adjustment of a primary beamlet of the plurality of primary beamlets.

Embodiment 2. The optical system of embodiment 1, wherein each first multipole of the plurality of first multipoles and each second multipole of the plurality of second multipoles form pairs of corresponding multipoles configured for individual focus adjustment of each primary beamlet of the plurality of primary beamlets.

Embodiment 3. The optical system of any of embodiments 1 or 2, wherein the first multipole arrangement and the second multipole arrangement comprise: a plurality of electrical connections to allow for individual adjustment of potentials per multipole.

Embodiment 4. The optical system of any of embodiments 1 to 3, wherein each of the first multipoles and the second multipoles are respective first quadrupoles and second quadrupoles.

Embodiment 5. The optical system of embodiment 4, wherein poles of the first quadrupoles and poles of the second quadrupoles are offset by an angle of 90° or 0°.

Embodiment 6. The optical system of any of any of embodiments 1 to 3, wherein each of the first multipoles and the second multipoles are octupoles.

Embodiment 7. The optical system according to any of embodiments 1 to 6, wherein the plurality of openings in the electrode body have a pitch of 0.5 mm or above.

Embodiment 8. A charged particle multi-beam apparatus having a plurality of primary beamlets focused on a specimen, comprising: a charged particle emitter for a primary charged particle beam; an aperture lens array for generating a plurality of primary beamlets from the primary charged particle beam; and an optical system according to any of embodiments 1 to 7.

Embodiment 9. The charged particle multi-beam apparatus according to embodiment 8, wherein the optical system is configured to act as an objective lens to focus a plurality of primary beamlets on the specimen.

Embodiment 10. The charged particle multi-beam apparatus according to any of embodiments 8 to 9, further comprising: a common pre-scan-deflector array configured to scan the primary beamlets; and a common scan-deflector array configured to scan the primary beamlets over the specimen.

Embodiment 11. The charged particle multi-beam apparatus according to embodiment 10, wherein the common pre-scan-deflector array and the common scan-deflector array are synchronized such that the scanning of the primary beamlets is generated by a combined action of the common pre-scan-deflector array and the common scan-deflector array.

Embodiment 12. The charged particle multi-beam apparatus according to any of embodiments 8 to 11, further comprising: a detector array position between the plurality of electrostatic lenses and the aperture lens array configured to detected signal beamlets, generated upon impingement of the primary beamlets on the specimen.

Embodiment 13. The charged particle multi-beam apparatus according to any of embodiments 8 to 12, further comprising: a collimator downstream of the aperture lens array and configured to deflect the plurality of primary beamlets with respect to each other; and an alignment system between the aperture lens array and the collimator, the alignment system being configured to provide at least one of a rotation, a deflection and a pitch adjustment of an array of primary beamlets provided by the plurality of primary beamlets.

Embodiment 14. The charged particle multi-beam apparatus according to any of embodiments 8 to 13, wherein a distance of the first multipole arrangement and the second multipole arrangement is 5 mm or above, particularly wherein a distance of the first multipole arrangement and the second multipole arrangement is 5 mm to 50 mm.

Embodiment 15. A method of focusing a plurality of primary beamlets of charged particles on a specimen, comprising: focusing the plurality of primary beamlets with a plurality of electrostatic lenses with three or more electrodes and a plurality of openings in each of the three or more electrodes; and adjusting a focal length individually for each of the plurality primary beamlets by introducing a first astigmatism to a primary beamlet of the plurality of primary beamlets and a second astigmatism to the primary beamlet of the plurality of primary beamlets, the first astigmatism and the second astigmatism compensate each other and provide an individual focus adjustment of the primary beamlet.

Embodiment 16. The method of embodiment 15, wherein the adjusting of the focal length further comprises: providing two or more first voltages to each first multipole of a plurality of first multipoles to generate the first astigmatism and providing two or more second voltages to each second multipole of a plurality of second multipoles to generate the second astigmatism.

Embodiment 17. The method of embodiment 16, wherein the focus adjustment is at least 0.3 micron per volt for at least one of the two or more first voltages and one of the two or more second voltages.

Embodiment 18. The method of any of embodiments 16 to 17, wherein each of the two or more first voltages and two or more second voltages are below 100 V for correcting the focus position of all of the plurality of primary beamlets in a plane of the specimen.

Embodiment 19. The method of any of embodiments 16 to 18, wherein a distance of the plurality of first multipoles and the plurality of second multipoles is 5 mm or above, particularly wherein a distance of the plurality of first multipoles and the plurality of second multipoles is 5 mm to 50 mm.

Embodiment 20. The method of any of embodiments 15 to 19, further comprising: scanning the plurality of primary beamlets.

Embodiments of the present disclosure provide a plurality of advantages, some of which are described in the following: an individual focus adjustment of primary beamlets of the plurality of primary beamlets can be provided. The voltages provided for adjustment are low as compared to a lens adjustment. In other words, the supply voltages for the focus adjustment are comparably small. Accordingly, the plurality of adjustment voltages may be more easily provided to the array of primary beamlets, which may be closely packed together, e.g. with a pitch of 400 μm to 4 mm. A stigmatic focus can be provided for the adjustment. The high throughput imaging and/or inspecting can be provided at low resolution (e.g. 10 nm or below).

While the foregoing is directed to embodiments, other and further embodiments may be devised without departing from the basic scope thereof, and the scope thereof is determined by the claims that follow.

We claim:

1. An optical system configured to focus a plurality of primary beamlets of a multi-beam apparatus, comprising:
a first optical component, comprising:
a first multipole arrangement with a plurality of first multipoles of an order of four or more, each first multipole of the plurality of first multipoles is configured to provide a first astigmatism; and
a second multipole arrangement with a plurality of second multipoles of an order of four or more, each second multipole of the plurality of second multipoles is configured to provide a second astigmatism, wherein the first astigmatism and the second astigmatism compensate each other;
the optical system further comprising:
a second optical component, comprising:
three or more electrodes forming a plurality of electrostatic lenses for the plurality of primary beamlets, each electrode comprising:
an electrode body and a plurality of openings in the electrode body for guiding one primary beamlet of the plurality of primary beamlets through one opening of the plurality of openings; and
an electrical connection to provide a potential to the electrode body at the plurality of openings;
wherein a first multipole of the plurality of first multipoles and a second multipole of the plurality of second multipoles form a pair of corresponding multipoles configured for individual focus adjustment of a primary beamlet of the plurality of primary beamlets.

2. The optical system of claim 1, wherein each first multipole of the plurality of first multipoles and each second multipole of the plurality of second multipoles form pairs of corresponding multipoles configured for individual focus adjustment of each primary beamlet of the plurality of primary beamlets.

3. The optical system of claim 1, wherein the first multipole arrangement and the second multipole arrangement comprise:
a plurality of electrical connections to allow for individual adjustment of potentials per multipole.

4. The optical system of claim 1, wherein each of the first multipoles and the second multipoles are respective first quadrupoles and second quadrupoles.

5. The optical system of claim 4, wherein poles of the first quadrupoles and poles of the second quadrupoles are offset by an angle of 90° or 0°.

6. The optical system of claim 1, wherein each of the first multipoles and the second multipoles are octupoles.

7. The optical system of claim 1, wherein the plurality of openings in the electrode body have a pitch of 0.5 mm or above.

8. A charged particle multi-beam apparatus having a plurality of primary beamlets focused on a specimen, comprising:
a charged particle emitter for a primary charged particle beam;
an aperture lens array for generating a plurality of primary beamlets from the primary charged particle beam; and
an optical system configured to focus a plurality of primary beamlets of a multi-beam apparatus, the optical system comprising:
a first optical component, comprising:
a first multipole arrangement with a plurality of first multipoles of an order of four or more, each first multipole of the plurality of first multipoles is configured to provide a first astigmatism; and
a second multipole arrangement with a plurality of second multipoles of an order of four or more, each second multipole of the plurality of second multipoles is configured to provide a second astigmatism, wherein the first astigmatism and the second astigmatism compensate each other;
the optical system further comprising:
a second optical component, comprising:
three or more electrodes forming a plurality of electrostatic lenses for the plurality of primary beamlets, each electrode comprising:
an electrode body and a plurality of openings in the electrode body for guiding one primary beamlet of the plurality of primary beamlets through one opening of the plurality of openings; and
an electrical connection to provide a potential to the electrode body at the plurality of openings;
wherein a first multipole of the plurality of first multipoles and a second multipole of the plurality of second multipoles form a pair of corresponding multipoles configured for individual focus adjustment of a primary beamlet of the plurality of primary beamlets.

9. The charged particle multi-beam apparatus according to claim 8, wherein the optical system is configured to act as an objective lens to focus a plurality of primary beamlets on the specimen.

10. The charged particle multi-beam apparatus according to claim 8, further comprising:
a common pre-scan-deflector array configured to scan the primary beamlets; and
a common scan-deflector array configured to scan the primary beamlets over the specimen.

11. The charged particle multi-beam apparatus according to claim 10, wherein the common pre-scan-deflector array and the common scan-deflector array are synchronized such that the scanning of the primary beamlets is generated by a combined action of the common pre-scan-deflector array and the common scan-deflector array.

12. The charged particle multi-beam apparatus according to claim 8, further comprising:
a detector array position between the plurality of electrostatic lenses and the aperture lens array configured to detected signal beamlets, generated upon impingement of the primary beamlets on the specimen.

13. The charged particle multi-beam apparatus according to claim 8, further comprising:
a collimator downstream of the aperture lens array and configured to deflect the plurality of primary beamlets with respect to each other; and
an alignment system between the aperture lens array and the collimator, the alignment system being configured to provide at least one of a rotation, a deflection and a pitch adjustment of an array of primary beamlets provided by the plurality of primary beamlets.

14. The charged particle multi-beam apparatus according to claim 8, wherein a distance of the first multipole arrangement and the second multipole arrangement is 5 mm or above, particularly wherein a distance of the first multipole arrangement and the second multipole arrangement is 5 mm to 50 mm.

15. A method of focusing a plurality of primary beamlets of charged particles on a specimen, comprising:
focusing the plurality of primary beamlets with a plurality of electrostatic lenses with three or more electrodes and a plurality of openings in each of the three or more electrodes; and
adjusting a focal length individually for each of the plurality primary beamlets by introducing a first astigmatism to a primary beamlet of the plurality of primary beamlets and a second astigmatism to the primary beamlet of the plurality of primary beamlets, the first astigmatism and the second astigmatism compensate each other and provide an individual focus adjustment of the primary beamlet.

16. The method of claim 15, wherein the adjusting of the focal length further comprises:
providing two or more first voltages to each first multipole of a plurality of first multipoles to generate the first astigmatism and providing two or more second voltages to each second multipole of a plurality of second multipoles to generate the second astigmatism.

17. The method of claim 16, wherein the focus adjustment is at least 0.3 micron per volt for at least one of the two or more first voltages and one of the two or more second voltages.

18. The method of claim 16, wherein each of the two or more first voltages and two or more second voltages are below 100 V for correcting the focus position of all of the plurality of primary beamlets in a plane of the specimen.

19. The method of claim 16, wherein a distance of the plurality of first multipoles and the plurality of second multipoles is 5 mm or above, particularly wherein a distance of the plurality of first multipoles and the plurality of second multipoles is 5 mm to 50 mm.

20. The method of claim 15, further comprising:
scanning the plurality of primary beamlets.
